(19) United States
(12) Patent Application Publication
(10) Pub. No.: US 2009/0170293 A1
(43) Pub. Date: Jul. 2, 2009

(54) METHOD FOR MANUFACTURING SEMICONDUCTOR DEVICE

(75) Inventor: Yusuke MATSUZAWA, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/342,115

(22) Filed: Dec. 23, 2008

(30) Foreign Application Priority Data
Dec. 28, 2007 (JP) 2007-340014

(51) Int. Cl. H01L 21/3205

(52) U.S. Cl. 438/486; 438/478; 438/488; 257/E21.295

(57) ABSTRACT

A method for manufacturing a semiconductor device includes forming a first semiconductor layer on a semiconductor substrate, forming a second semiconductor layer on the first semiconductor layer, etching the second semiconductor layer and the first semiconductor layer to form a first groove passing through the second semiconductor layer and the first semiconductor layer, forming a support in the first groove, etching the second semiconductor layer to form a second groove that exposes the first semiconductor layer, forming a cavity between the second semiconductor layer and the semiconductor substrate by etching the first semiconductor layer through the second groove, forming a semiconductor film in the cavity, and thermally oxidizing the semiconductor film.

### BACKGROUND

1. Technical Field

The present invention relates to a method for manufacturing a semiconductor device, and more particularly to a technique for partially forming a so-called silicon-on-insulator (SOI) structure on a semiconductor substrate.

2. Related Art

Regarding a field-effect transistor (FET) formed on an SOI substrate, its usefulness is attracting attention in respects of ease of isolation, freedom from latch-up, and smallness of source/drain junction capacitance.

In particular, regarding a fully-depleted SOI transistor, which is easily driven at a low voltage due to its low power consumption and high speed operation, researches on the operation of an SOI transistor in a fully-depleted mode are actively performed.

As an example of the SOI substrate, a separation by implanted oxygen (SIMOX) substrate and a bonded substrate are used.

However, their manufacturing methods are both special, and therefore these substrates cannot be produced in a typical complementary metal oxide semiconductor (CMOS) process.

To overcome this disadvantage, there is known a method of separation by bonding silicon islands (SBSI) in which an SOI structure is produced from an ordinary bulk silicon wafer through a typical CMOS process.

Refer to, for example, T. Sakai et al., “Separation by Bonding Si Islands (SBSI) for LSI Application”, Second International SiGe Technology and Device Meeting, Meeting Abstract, pp. 230-231, May (2004).

The SBSI method will be described below with reference to the drawings.

FIGS. 11A to 13B show a method for manufacturing a semiconductor device according to an example of the related art.

Among FIGS. 11A to 13B, FIGS. 11A, 12A and 13A are plan views and FIGS. 11B, 12B and 13B are sectional views taken along the lines X11-X′11, X12-X′12 and X13-X′13 of FIGS. 11A, 12A and 13A, respectively.

As shown in FIGS. 11A and 11B, a film of a silicon germanium (SiGe) layer 111 and a film of a Si layer 113 are first formed in sequence on a silicon (Si) substrate 101, and grooves h′1 for a support are formed in the films.

The Si layer 113 and the SiGe layer 111 are formed by an epitaxial growth method, and the grooves h′1 for a support are formed by dry etching.

After a support film is formed over the entire surface of the Si substrate 101, the support film is dry etched, thereby forming a support 122 as shown in FIGS. 12A and 12B.

Further, the Si layer 113 and the SiGe layer 111 exposed below the support 122 are also dry etched.

In this state, when the SiGe layer 111 is etched with a fluoro-nitric acid solution from the directions of arrows of FIG. 12A, a cavity 125 is formed under the Si layer 113 in the form where the Si layer 113 is hanging from the support 122.

Next, as shown in FIGS. 13A and 13B, the Si substrate 101 is thermally oxidized, thereby forming a silicon oxide (SiO₂) film 131 in the cavity 125 (oxidation process for a buried oxide (BOX)).

In this way, an SOI structure composed of the silicon oxide (SiO₂) film 131 and the Si layer 113 is formed on the bulk Si substrate (i.e., bulk silicon wafer) 101.

The SiO₂ film 131 is also referred to as a “BOX layer”, and the Si layer 113 is also referred to as an “SOI layer”.

After the formation of the SOI structure, a SiO₂ film (not shown) is formed over the entire surface of the Si substrate 101 by chemical vapor deposition (CVD).

The SiO₂ film and the support 122 are then planarized by chemical mechanical polishing (CMP), and are wet etched with a hydrofluoric acid (HF) solution (i.e., HF etching), thereby exposing the surface of the Si layer 113.

As described above, the SBSI method is a very effective method in that a device formed in the SOI layer (hereinafter referred to as an “SOI device”) can be provided at a low cost, and that a device formed directly on a bulk Si subtrate (hereinafter referred to as a “bulk Si device”) as well as the SOI device can easily be mounted together on the same substrate.

However, when an SOI device formed by the SBSI method and a typical SOI device formed from an SOI wafer are compared to each other, there is no difference between them in terms of performance.

Therefore, from the viewpoint of strengthening advantages of the SBSI method, it has been desired to improve the performance of the SOI device formed by the SBSI method by taking advantages of the structure unique to SBSI processes.

On the other hand, performance improvements, such as an increase in speed and a decrease in size, are achieved by advancing miniaturization in the current typical semiconductor devices.

However, such performance improvements due to miniaturization are close to the limit, and therefore a variety of enterprises and research institutions attempt to achieve improvements in device performance in ways other than miniaturization.

One of measures to improve performance is a technique to apply stress onto a region that will become a channel (hereinafter referred to as a “channel region”) so as to enhance mobility of carriers.

That is, there is a so-called strained Si channel technique.

For example, refer to Tsutomu Tezuka et al. , “Fabrication and Electrical Characterization of Strained Si-on-insulator/Strained SiGe-on-insulator Dual Channel CMOS structures with High-Mobility Channels”, IEEJ Transactions on Electronics, Information and Systems, Vol. 126 (2006), No. 11, pp. 1332-1339.

The strained Si channel technique is roughly divided into global strain techniques as exemplified in SiGe on insulator (SGOI) and strained Silicon on insulator (SSOI) and local strain techniques using a nitride film and so on.

It is a fact generally known that, as shown in FIG. 14, when tensile stresses are provided in a direction substantially in parallel to the channel in plan view (hereinafter referred to as a “channel parallel direction”) and tensile stresses are provided in a direction substantially vertical to the channel in plan view (hereinafter referred to as a “channel vertical direction”), mobility of electrons is enhanced.

For example, refer to A. V-Y. Thean et al., “Uniaxial-Biaxial Stress Hybridization For Super-Critical Strained-Si Directly On Insulator (SC-SSOI) PMOS With Different Channel Orientation”, IEDM 05-515.

As shown in FIGS. 11A to 13B, the SBSI method has unique processes such as a process of forming a support, a process of forming a cavity, and a process of filling the cavity.

In an SOI device formed by such processes (hereinafter referred to as an “SBSI device”), the SOI layer is partially (i.e., island-like) formed in plan view.

Strain techniques in the related art, such as SGOI and SSOI, cannot therefore be applied to the SBSI method.

There has not been achieved an SBSI device (i.e., an SOI device formed by an SBSI method) in which strain is provided in the channel region so as to enhance the mobility of electrons.

### SUMMARY

An advantage of the present invention is to provide a method for manufacturing a semiconductor device that enables achievement of an SBSI device with enhanced mobility of electrons.

FIG. 9 is experiment results conducted by the present inventor, and is a graph showing a relationship between curvature of a wafer and mobility.

In FIG. 9, the horizontal axis represents a gate voltage Vg, and the vertical axis represents mobility.

At this point, as shown in FIG. 10, a wafer having a transistor made by ordinary processes mounted thereon is placed on a plate, and this plate is curved in a convex shape.

In this state, electric characteristics of the transistor are measured.

The plate is made of a material that is deformable at normal room temperature.

The plate is mounted on a cylindrical metal plate, and mechanical forces are added onto the both sides of the plate by using a jig, enabling the plate to be curved in a convex shape.

As shown in FIG. 9, when a comparison is made between a plate that is not curved (i.e., without curvature) and a curved plate (i.e., convex curvature), it is confirmed that the plate with convex curvature has higher mobility.

This is because tensile stress is given to the channel region due to the convex curvature.

The present invention is made based on such discovery (i.e., the discovery that if tensile stress is given under a condition where a wafer is curved in a convex shape in sectional view by some sort of force, mobility improves).

A method for manufacturing a semiconductor device according to an aspect of the invention includes (a) forming a first semiconductor layer on a semiconductor substrate, (b) forming a second semiconductor layer on the first semiconductor layer, (c) etching the second semiconductor layer and the first semiconductor layer to form a first groove passing through the second semiconductor layer and the first semiconductor layer, (d) forming a support in the first groove, (e) etching the second semiconductor layer to form a second groove that exposes the first semiconductor layer, (f) forming a cavity between the second semiconductor layer and the semiconductor substrate by etching the first semiconductor layer through the second groove, (g) forming a semiconductor film in the cavity, and (h) thermally oxidizing the semiconductor film.

The “semiconductor substrate” according to the aspect of the invention is, for example, a bulk silicon (Si) substrate, the “first semiconductor layer” is, for example, a single-crystal silicon germanium (SiGe) layer, and the “second semiconductor layer” is, for example, a single-crystal Si layer.

The SiGe layer and the Si layer can be formed, for example, by an epitaxial growth method.

The “support” according to the aspect of the invention is made of an insulating film, such as a silicon oxide (SiO₂) film or a silicon nitride (Si₃N₄) film.

Further, the “semiconductor film” according to the aspect of the invention is, for example, an amorphous silicon (a-Si) or polycrystalline silicon (poly-Si) film.

According to the foregoing method, when the semiconductor film is thermally oxidized to form an oxide film, the semiconductor layer can be curved in a convex shape in sectional view by volume expansion associated with the composition change from the semiconductor film to the oxide film.

Accordingly, the second semiconductor layer can be provided with forces pulling the layer towards the outside (i.e., tensile stress).

Providing such stress enables the second semiconductor layer to have strain to improve mobility of electrons.

In the foregoing method, it is preferable that step (g) be forming the semiconductor film in the cavity so as to fill an end on the first groove side of the cavity and leave behind a space at the center part of the cavity.

According to such a method, oxidation of the semiconductor film does not proceed in the end on the first groove side of the cavity, whereas oxidation of the semiconductor film proceeds at the center part of the cavity.

As a result, volume expansion is more remarkable at the center part than in the end on the first groove side of the cavity.

This facilitates curving of the second semiconductor layer in a concave shape in sectional view.

It is preferable that the foregoing method further include, between step (f) and step (g), (i) thermally oxidizing both a front surface of the semiconductor substrate and a back surface of the second semiconductor layer that face an inside of the cavity to form an underlying oxide film.

It is also preferable that, in step (g), the semiconductor film be formed in the cavity having the underlying oxide film formed therein.

According to such a method, it can be prevented that when a semiconductor film is thermally oxidized to form an oxide film, the second semiconductor layer, following the semiconductor film, is continuously oxidized.

In this case, it is preferable that supposing that a width of the cavity is W1 and a maximum width of a space left behind in the cavity after formation of the underlying oxide film is W2, a target value Tox of a thickness of the underlying oxide film formed both above and below the cavity be set to be equal to the W1, and a target value Tdepo of a film thickness of the semiconductor film formed both above and below the cavity be set in a range of (W2−50 [Angstrom])/2>Tdepo>W2/4.

Here, the “width of the cavity” means the height of the cavity in sectional view.

The “maximum width of the cavity” means the maximum height of the space in sectional view.

According to such a method, the second semiconductor layer can be curved in a convex shape with good reproducibility.

In the foregoing method, it is preferable that the semiconductor film be a semiconductor film of an amorphous structure.

According to such a method, the filling properties of the semiconductor film to the cavity can be enhanced as compared to the case of using a semiconductor film of a polycrystalline structure.

This allows a semiconductor film to be easily formed even in a deep portion of the cavity.

In the foregoing method, it is preferable that the semiconductor film be a semiconductor film of a polycrystalline structure.

According to such a method, the close contact of the semiconductor films deposited from the upper and lower directions in the cavity can be enhanced as compared to the case of using a semiconductor film of an amorphous structure.

For example, this allows the semiconductor film with a small space to be easily formed in the ends on the sides of the first grooves of the cavity.

It is preferable that the foregoing method further include, between step (g) and step (h), (j) performing a heat treatment for the semiconductor film of the amorphous structure to poly-crystallize the semiconductor film.

According to such a method, both the filling properties of the semiconductor film to the cavity and the close contact of the semiconductor films can be enhanced.

In the foregoing method, it is preferable that the semiconductor film be silicon.

### BRIEF DESCRIPTION OF THE DRAWINGS

The invention will be described with reference to the accompanying drawings, wherein like numbers reference like elements.

FIGS. 1A to 1C show a method for manufacturing a semiconductor device according to an embodiment (first drawings)

FIGS. 2A to 2C show the method for manufacturing a semiconductor device according to the embodiment (second drawings).

FIGS. 3A and 3B are views for illustrating a method to set film thicknesses (first drawings).

FIGS. 4A and 4B are views for illustrating the method to set film thicknesses (second drawings).

FIGS. 5A and 5B are views for illustrating the method to set film thicknesses (third drawings).

FIGS. 6A and 6B are views for illustrating the method to set film thicknesses (fourth drawings).

FIG. 7A is a plan view schematically showing an SOI structure after the CMP process, and FIG. 7B is an observation view obtained by a scanning electron microscope (SEM).

FIG. 8 shows a method for manufacturing a semiconductor device according to another embodiment.

FIG. 9 is a graph showing a relationship between curvature of a wafer and mobility.

FIG. 10 shows the state of an experiment.

FIGS. 11A and 11B show a method for manufacturing a semiconductor device according to an example of the related art (first drawings).

FIGS. 12A and 12B show the method for manufacturing a semiconductor device according to the example of the related art (second drawings).

FIGS. 13A and 13B show the method for manufacturing a semiconductor device according to the example of the related art (third drawings).

FIG. 14 shows directions of stresses for improving mobility.

### DESCRIPTION OF EXEMPLARY EMBODIMENT

An embodiment of the invention will now be described with reference to the accompanying drawings.

### (1) Manufacturing Processes

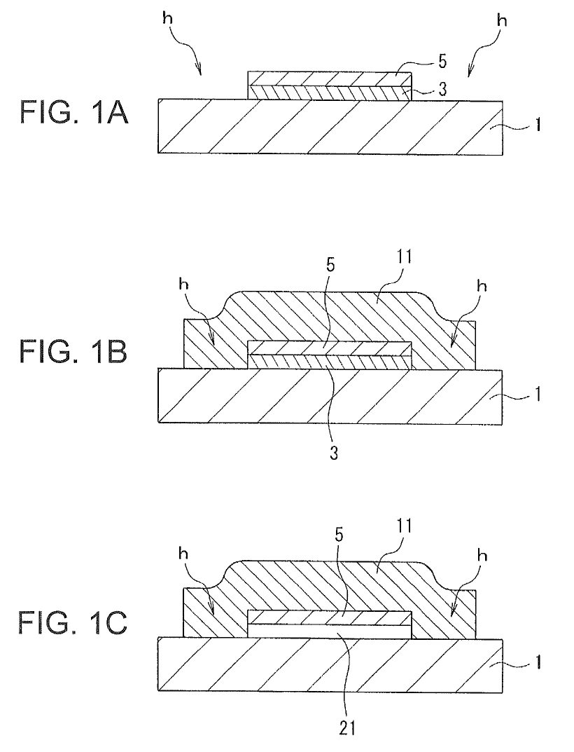

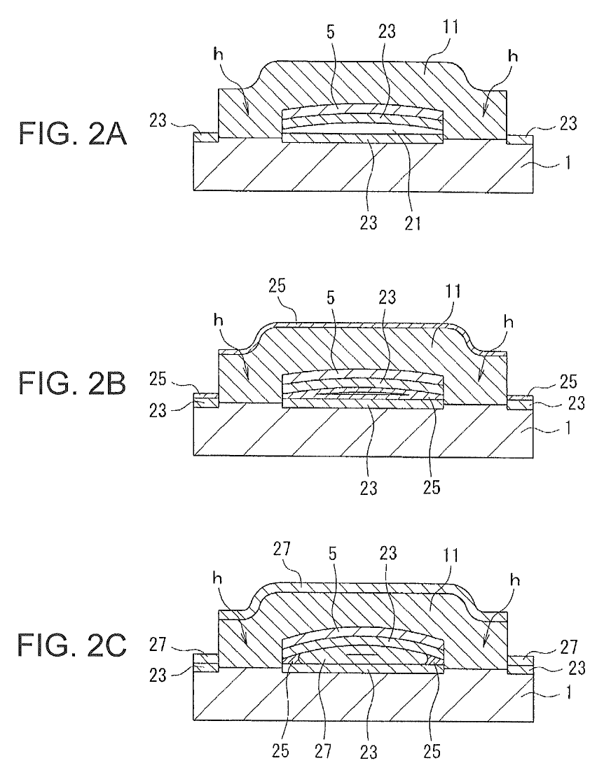

FIGS. 1A to 2C are sectional views showing a method for manufacturing a semiconductor device according to the embodiment of the invention.

With reference to FIG. 1A, a single-crystal silicon germanium (SiGe) layer 3 is first formed on a bulk silicon (Si) substrate 1, and a single-crystal Si layer 5 is formed on the SiGe layer 3.

These SiGe layer 3 and Si layer 5 are continuously formed, for example, by an epitaxial growth method.

Next, the Si layer 5 and the SiGe layer 3 are partially etched by a photolithography technique and an etching technique.

Support holes h with the Si substrate 1 serving as the bottom surfaces are thus formed in an area overlapping the isolation region (i.e., the region where an SOI structure is not formed) in plan view.

In this etching process, etching may be stopped at the surface of the Si substrate 1, and the Si substrate 1 may also be overetched to form a recess.

As shown in FIG. 1B, a support 11 made of a SiO₂ film is formed, and grooves with the Si substrate 1 serving as the bottom surfaces are formed in areas (areas on the front side and on the rear side of the page space, though they are not shown) overlapping the isolation region in plan view.

In the process of forming grooves, etching may be stopped at the surface of the Si substrate 1, and the Si substrate 1 may also be overetched to form a recess.

Next, as shown in FIG. 1C, a fluoro-nitric acid solution, for example, is brought into contact with side surfaces of each of the Si layer 5 and the SiGe layer 3 through the grooves, which are not shown, so that SiGe layer 3 is selectively etched and removed.

A cavity 21 is thus formed between the Si layer 5 and the Si substrate 1.

In wet etching using a fluoro-nitric acid solution, the etching rate of SiGe is greater than that of Si (i.e., high etching selectivity to Si), allowing only the SiGe layer 3 to be removed by etching while leaving behind the Si layer 5.

After formation of the cavity 21, the Si layer 5 is supported by the support (SiO₂ film) 11.

Note that, in the foregoing process of etching the SiGe layer 3, fluorine nitrate/hydrogen peroxide mixture, ammonia/hydrogen peroxide mixture, or fluorine acetate/hydrogen peroxide mixture may be used instead of the fluoro-nitric acid solution.

In this case, the etching rate of SiGe is greater than that of Si, allowing the SiGe layer to be selectively removed.

Next, the entire Si substrate 1 is thermally oxidized.

As shown in FIG. 2A, a SiO₂ film 23 is formed on the front surface of the Si substrate 1 and the back surface of the Si layer 5 that face the inside of the cavity 21, while a space is left behind in the entire cavity 21.

Note that, in this thermal oxidation process, the Si layer 5 becomes slightly curved in a convex shape in sectional view due to a difference in coefficient of thermal expansion between the support (SiO₂ film) 11 and the Si layer 5.

Next, an amorphous silicon (a-Si) film is deposited on the Si substrate 1, for example, by a CVD method.

As shown in FIG. 2B, an a-Si film 25 is thus formed in the cavity 21 with a space left behind at least at the center part of the cavity 21.

Note that, in this process of forming the a-Si film 25, conditions for forming the a-Si film 25 (e.g., thickness) are preferably adjusted so that ends of the cavity on the sides of the support holes h are completely filled as shown in FIG. 2B.

Next, the entire Si substrate 1 is thermally oxidized.

By this thermal oxidation, as shown in FIG. 2C, the a-Si film in the cavity is thermally oxidized to form a SiO₂ film 27.

In this thermal oxidation process, the center part (i.e., channel region) of the Si layer 5 is curved in a more convex shape due to the difference in coefficient of thermal expansion between the support (SiO₂ film) 11 and the Si layer 5 and due to the volume expansion associated with the composition change from the a-Si film 25 to the SiO₂ film 27.

Note that, as shown in FIG. 2B, ends of the cavity on the sides of the support holes h are completely filled, thereby making it difficult for oxygen and the like to be supplied to the ends.

Therefore, oxidation of the a-Si film 25 does not proceed well.

On the other hand, a space is left behind at the center part of the cavity, and therefore oxidation of the a-Si film proceeds.

As a result, volume expansion is more remarkable in the center part than in the ends of the cavity on the sides of the support holes h.

This makes it easy to curve the Si layer 5 in a convex shape in sectional view.

In this thermal oxidation process, both the back surface of the Si layer 5 and the front surface of the Si substrate 1 that face the inside of the cavity are covered with the SiO₂ film.

Therefore, if the a-Si film is excessively oxidized, oxidization can be prevented from proceeding to the back surface of the Si layer 5 and the front surface of the Si substrate 1.

As a result, for example, unintended reduction of the thickness of the Si layer 5 can be prevented.

Next, for example, a SiO₂ film (not shown) is deposited on the Si substrate 1, for example, by a CVD method to completely fill grooves (on the front side and the rear side of the page space).

At this point, if a space is left behind in a cavity, the cavity may be completely filled in this SiO₂ film formation process.

The following processes are the same as those in the SBSI method in the related art.

That is, the SiO₂ film is removed while being planarized, for example, by CMP to expose the surface of the Si layer 5.

Thus, an SOI structure composed of the SiO₂ film (i.e., BOX layer) 27 and the Si layer (i.e., SOI layer) 5 is completed on the bulk Si substrate 1.

Note that, in the foregoing planarization process, it is preferable that the CMP be stopped in a state where the slight SiO₂ film 27 is left on the Si layer 5, and the remaining SiO₂ film be removed by wet etching, for example, using diluted HF (DHF) or the like.

This can prevent the surface of the Si layer 5 from the damage by CMP.

Thereafter, for example, a MOS transistor is formed in the Si layer 5.

Specifically, a gate insulating film (not shown) is formed on the surface of the Si layer 5.

The gate insulating film is, for example, a SiO₂ film or a silicon oxynitride film (SiON) formed by thermal oxidation, or a High-K material film.

Next, a polycrystalline silicon (poly-Si) film is formed on the entire surface of the SOI substrate on which the gate insulating film is formed.

The formation of the polycrystalline silicon film is performed, for example, by a CVD method.

At this point, an impurity is introduced into the polycrystalline silicon film by ion implantation, in-Situ or the like to provide a polycrystalline silicon film with conductivity.

Next, the polycrystalline silicon film is partially etched by a photolithography technique and an etching technique to form a gate electrode (not shown).

Then, an impurity is ion implanted into the Si layer 5 with the gate electrode serving as a mask and a heat treatment is performed to form a source or drain (not shown).

Thus, the MOS transistor is completed.

### (2) Method to Set the Film Thickness

An example of a method to set the thickness of the SiO₂ film 27 and the thickness of the a-Si film 25 is described.

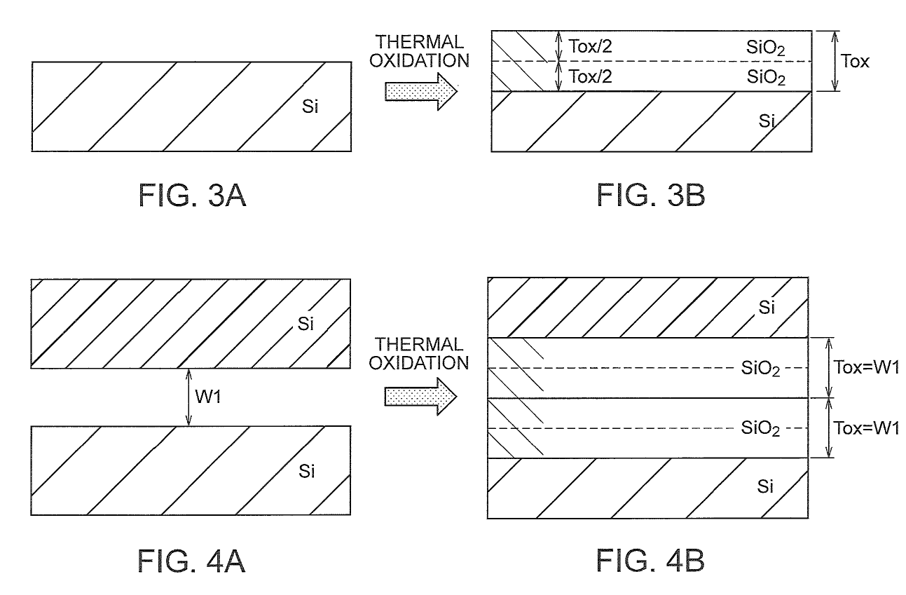

FIGS. 3A to 6B are sectional views illustrating a method to set the above film thicknesses.

As shown in FIGS. 3A and 3B, in a process of oxidation of Si, supposing that the thickness of a SiO₂ film formed by oxidizing the Si is Tox, SiO₂ films each having a thickness of Tox/2, up and down, are formed with the original Si surface serving as the center.

That is, the relationship of an amount of consumption of Si to a film thickness of formed SiO₂ is 1 to 2.

Accordingly, as shown in FIGS. 4A and 4B, when a cavity is filled with SiO₂ growing from the top and bottom, upper and lower SiO₂ films are completely brought into close contact with each other to eliminate a space, supposing that the target value of each thickness of upper and lower SiO₂ films is a cavity width W1 (i.e., the film thickness of the SiGe layer).

However, such complete adhesion of SiO₂ film is accomplished in an ideal state without curvature in upper and lower Si films.

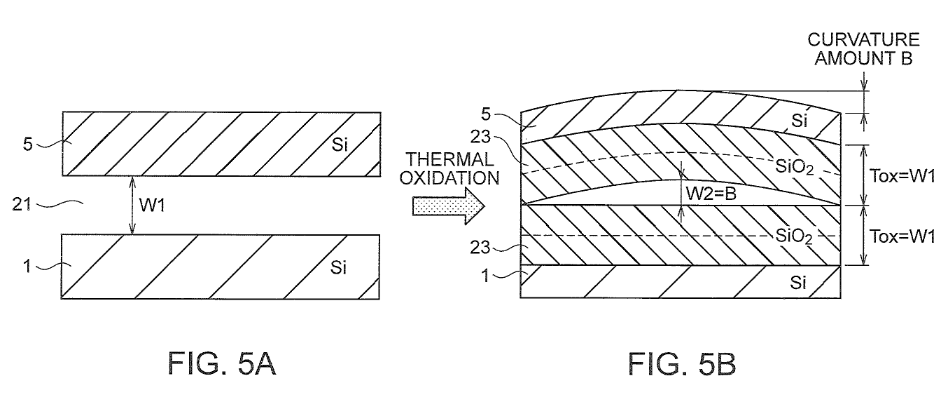

On the other hand, in the case of actual SBSI with curvature in the Si layer 5 as shown in FIGS. 5A and 5B, supposing that the target value of the thickness of the SiO₂ films 23 growing from the top and bottom is W1, upper and lower SiO₂ films 23 are brought into close contact with each other at the outermost edges on the support hole sides.

However, the closer to the center the position of a space is, the larger the width of the space is.

At this point, the maximum space width W2 is equal to a curvature amount B.

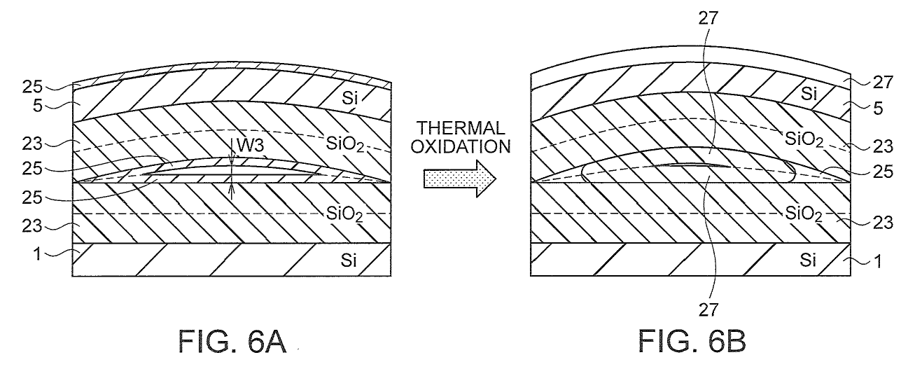

As shown in FIGS. 6A and 6B, in order to curve the Si layer 5 in a more convex shape by oxidation through a space after filling the cavity with the a-Si film 25 (or a poly-Si film 35 to be described later), a space W3 needs to be left behind in the cavity after the a-Si film 25 (or the poly-Si film 35)is filled.

An appropriate range of W3 is represented, for example, by the following expression (1).

50 [Angstrom]<W3<W2/2 (1)

The range of a filling amount of the a-Si film 25 (or the poly-Si film 35), that is, the total thickness Tfill of the film deposited in the cavity, at this point, is represented, for example, by the following expression (2).

W2−50>Tfill>W2−W2/2=W2/2 (2)

In the deposition process of the a-Si film 25 (or the poly-Si film 35) by CVD, the cavity is filled with the a-Si film 25 (or the poly-Si film 35) growing from the top and the bottom.

Accordingly, the range of a deposition amount (i.e., film thickness) Tdepo of the a-Si film 25 (or the poly-Si film 35) is represented, for example, by the following expression (3).

(W2−50)/2>Tdepo>W2/4 (3)

As such, to form the Si layer 5 in an upward convex, it is preferable that the target value Tox of the thickness of the SiO₂ film 23 be equal to the cavity width W1 (=thickness of the SiGe film), and it is also preferable that the deposition amount Tdepo of the a-Si film 25 (or the poly-Si film 35) be set to satisfy the expression (3).

Note that, as shown in FIG. 5B, W2 means the maximum space width left behind in the cavity after BOX oxidation, and is equal to the active curvature amount B after BOX oxidation.

In the foregoing embodiment, it is recommended as an example that the target value Tox of the thickness of the SiO₂ film 23 be set to be 300 [Angstrom].

For example, the active curvature amount B (=W2) at this point is, for example, 500 [Angstrom].

Further, it is recommended that the deposition amount Tdepo of the a-Si film 25 (or the poly-Si film 35) be, for example, 200 [Angstrom].

Setting of Tdepo=200 [Angstrom] when W2=500 [Angstrom] means that Tdepo is set to be thick as apparent from the expression (3′).

This is because setting Tdepo to be thick reduces the space finally left in the cavity.

From the viewpoint of preventing an etchant from penetration, the space finally left in the cavity is preferably small.

225 [Angstrom]>Tdepo>125 [Angstrom] (3′)

As described above, according to the embodiment of the invention, when the a-Si film 25 is thermally oxidized to form the SiO₂ film 27, the Si layer 5 can be curved in a convex shape in sectional view by volume expansion associated with the composition change from the a-Si film 25 to the SiO₂ film 27.

Accordingly, forces pulling the layer outward (i.e., tensile stress) can be given to the Si layer 5.

Providing such stress enables the Si layer 5 to have strain to improve mobility of electrons.

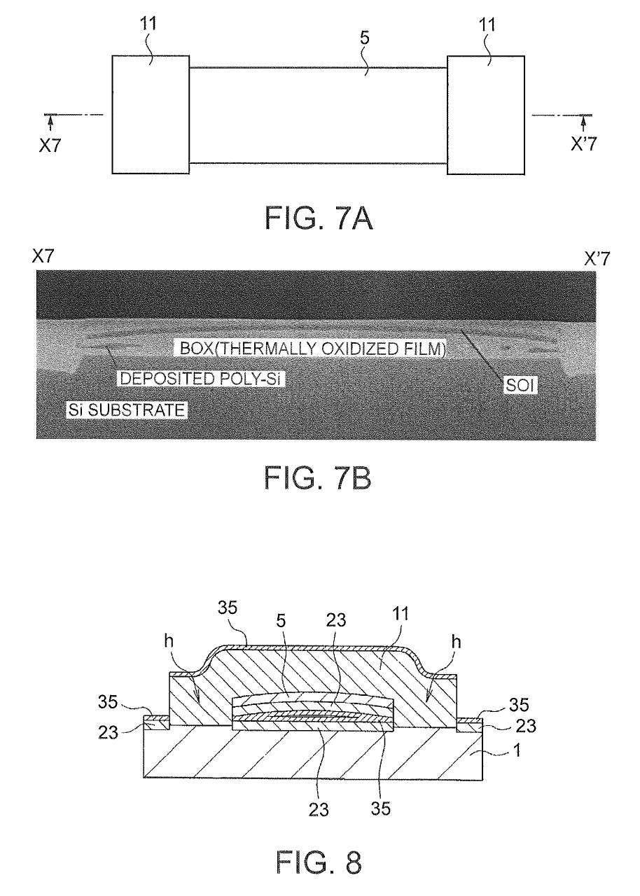

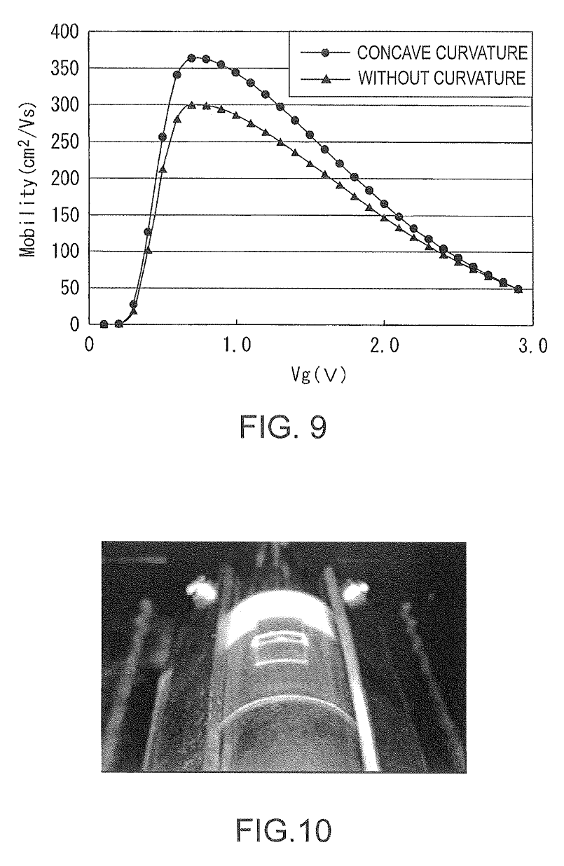

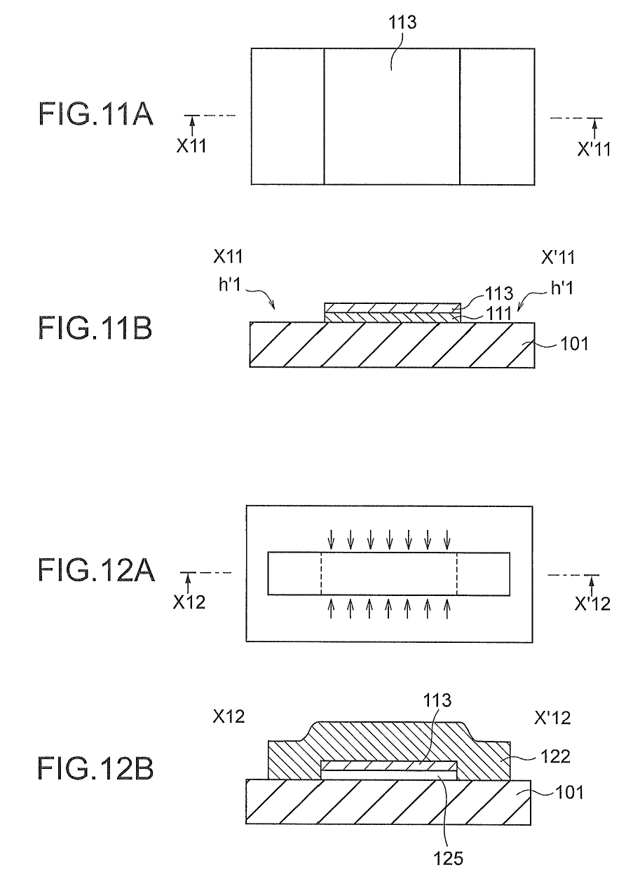

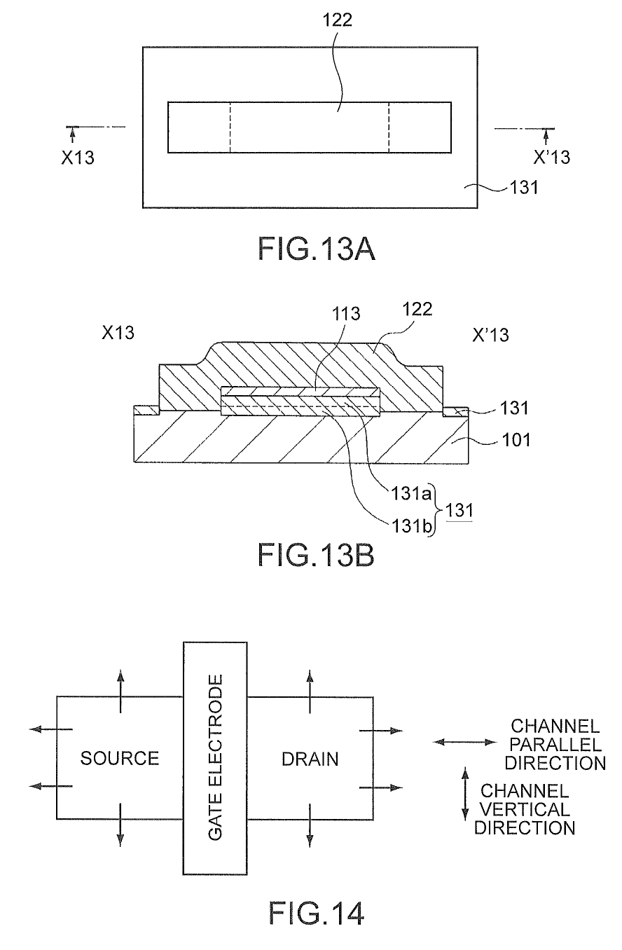

FIG. 7A is a plan view schematically showing the SOI structure after the CMP process.

FIG. 7B is a view obtained by cutting the above SOI structure along the line X7-X′7 and taking a photograph of the cut portion by a SEM.

As shown in FIG. 7B, it has been confirmed that the BOX layer has a swelling at the center part by the foregoing manufacturing method and the SOI layer is curved in a convex shape in sectional view along the swelling.

Due to the curvature in the convex shape, tensile stress is given to the whole Si layer 5, so that the Si layer 5 has strain.

In this embodiment, the Si substrate 1 corresponds to the “semiconductor substrate”, and the SiGe layer 3 corresponds to the “first semiconductor layer” of the invention.

The Si layer 5 corresponds to the “second semiconductor layer” of the invention, and the support holes h correspond to the “first grooves” of the invention.

Further, grooves formed on the front side and the rear side of the page space correspond to “second grooves” of the invention, and the a-Si film 25 corresponds to the “semiconductor film” of the invention.

The SiO₂ film 23 corresponds to the “underlying oxide film” of the invention, and the SiO₂ film 27 corresponds to the “oxide film” of the invention.

It should be noted that the case of using the a-Si film 25 as an example of the “semiconductor film” of the invention has been described in the foregoing embodiment, but the invention is not limited to the embodiment.

As an example of the “semiconductor film” mentioned above, the polycrystalline silicon (poly-Si) film 35 may be used as shown in FIG. 8.

Even with such a configuration, tensile stress can be provided to the Si layer 5 in the channel region to cause the layer to have strain, resulting in improved mobility of electrons.

Here, advantages of the a-Si film 25 and the poly-Si film 35 in the invention are described.

If the a-Si film 25 is used as the “semiconductor film”, the filling properties of the Si film to the cavity 21 can be enhanced as compared to the case of using the poly-Si film 35, allowing the Si film to be easily formed in a deep portion of the cavity 21.

If the poly-Si film 35 is used as the “semiconductor film”, the close contact of the Si films deposited from the upper and lower directions in the cavity 21 can be enhanced as compared to the case of using the a-Si film 25.

For example, this allows the Si film with a small space to be easily formed in the ends of the cavity 21 on the sides of the support holes h.

Furthermore, as the “semiconductor film” in the invention, the a-Si film 25 may be first deposited and a heat treatment may be performed for the a-Si film 25 concerned to be poly-crystallized prior to thermal oxidation for forming the SiO₂ film 27.

That is, prior to forming the SiO₂ film 27, the a-Si film 25 may be transformed into the poly-Si film 35 by a heat treatment.

This method can enhance the filling properties of the Si film to the cavity 21 as well as the close contact of the Si film in the cavity 21, enabling the SiO₂ film 27 with a small space to be formed in the thermal oxidation process to be performed later.

What is claimed is:

1. A method for manufacturing a semiconductor device, comprising:
(a) forming a first semiconductor layer on a semiconductor substrate;
(b) forming a second semiconductor layer on the first semiconductor layer;
(c) etching the second semiconductor layer and the first semiconductor layer to form a first groove passing through the second semiconductor layer and the first semiconductor layer;
(d) forming a support in the first groove;
(e) etching the second semiconductor layer to form a second groove that exposes the first semiconductor layer;
(f) forming a cavity between the second semiconductor layer and the semiconductor substrate by etching the first semiconductor layer through the second groove;
(g) forming a semiconductor film in the cavity; and
(h) thermally oxidizing the semiconductor film.

2. The method for manufacturing a semiconductor device according to claim 1, wherein step (g) is forming the semiconductor film in the cavity so as to fill an end on the first groove side of the cavity and leave behind a space at a center part of the cavity.

3. The method for manufacturing a semiconductor device according to claim 1, further comprising, between step (f) and step (g), (i) thermally oxidizing both a front surface of the semiconductor substrate and a back surface of the second semiconductor layer that face an inside of the cavity to form an underlying oxide film; and wherein, in step (g), the semiconductor film is formed in the cavity having the underlying oxide film formed therein.

4. The method for manufacturing a semiconductor device according to claim 3, wherein a target value Tox of a thickness of the underlying oxide film formed both above and below the cavity is set to be equal to W1, and a target value Tdepo of a film thickness of the semiconductor film formed both above and below the cavity is set in a range of (W2−50 (Angstrom))/2>Tdepo>W2/4, wherein the W1 is a width of the cavity and the W2 is a maximum width of a space left behind in the cavity after formation of the underlying oxide film.

5. The method for manufacturing a semiconductor device according to claim 1, wherein the semiconductor film is a semiconductor film of an amorphous structure.

6. The method for manufacturing a semiconductor device according to claim 1, wherein the semiconductor film is a semiconductor film of a polycrystalline structure.

7. The method for manufacturing a semiconductor device according to claim 5, further comprising, between step (g) and step (h), (j) performing a heat treatment for the semiconductor film of the amorphous structure to poly-crystallize the semiconductor film.

8. The method for manufacturing a semiconductor device according to claim 1, wherein the semiconductor film is silicon.
